(19) United States
(12) Patent Application Publication
(10) Pub. No.: US 2002/0093632 A1
(43) Pub. Date: Jul. 18, 2002

(54) Three-dimensional fabrication using entangled-photon lithography

(76) Inventors: Malvin C. Teich, Boston, MA (US); Bahaa E.A. Saleh, Lexington, MA (US); Alexander V. Sergienko, Boston, MA (US); John Fourkas, Chestnut Hill, MA (US)

Correspondence Address: FOLEY, HOAG & ELIOT, LLP, PATENT GROUP, ONE POST OFFICE SQUARE, BOSTON, MA, 02109, US

(21) Appl. No.: 09/939,017

(22) Filed: Aug. 25, 2001

Related U.S. Application Data
(60) Provisional application No. 60/228,576, filed on Aug. 29, 2000.

(51) Int. Cl. G03B 27/00; G03F 7/20

(52) U.S. Cl. 355/18; 430/322; 430/394; 355/77

(57) ABSTRACT

The present invention relates to novel three-dimensional fabrication using entangled-photon lithography. The systems include a source of light that produces twin or multiply entangled photons. The systems also include optical components that direct the twin or multiply entangled photons towards an interaction region. The interaction region includes absorption means responsive to a particular range of energies, which approximately equals the sum of the energies of the entangled photons. The systems may further include fabrication means in the interaction region that are responsive to physical and/or chemical changes of material or materials in this region, including the deposition or addition of one or more species, the removal of one or more species, the combination of two or more species, and/or the conversion of one species to another. The present invention also relates to methods for the three-dimensional fabrication of a structure through the use of twin or multiply entangled photons, at least some of which are spatially distinct from one another after their generation. The entangled photons are directed to come together at the interaction region, thereby allowing the absorption of entanglement-related photons at selected and adjustable points, in three dimensions, in the structure to be fabricated.

### CROSS REFERENCE TO RELATED APPLICATIONS

This application claims the benefit of the U.S. Provisional Application No. 60/228,576, filed on Aug. 29, 2000.

### BACKGROUND OF THE INVENTION

We propose a new technique of multi-photon lithography for fabricating three-dimensional structures (including semiconductors, photonic materials, optical integrated circuits, microfluidic devices, microsensor devices, biochips, micro-electro-mechanical (MEMS) devices, and other structures that comprise chemical, electrical, optical, and mechanical elements) using a light source consisting of entangled (or otherwise correlated) photon clusters generated, for example, by the process of nonlinear optical parametric downconversion.

This invention provides a substantial improvement over the current process of fabrication using ordinary light, which involves the absorption of photons one-at-a-time, which has become an established method of fabricating two-dimensional objects and, with great difficulty, can be used to fabricate rudimentary three-dimensional objects. The arrival of photons in the conventional technique allows fabrication to take place only one layer at a time, whereas with the proposed technique, an entire volume can be instantaneously sculpted to the specifications desired in three dimensions.

The invention also provides substantial advantages over the process of fabrication using the absorption of multiple, un-entangled photons. While this latter process can also be used to fabricate three-dimensional objects, it requires high-intensity light, usually from an ultrafast laser source. The use of short laser pulses additionally does not allow this latter technique to be employed with significant spectral resolution.

The invention is fundamentally different from the process of fabrication of gratings using interference fringes and entangled photons, as presented in U.S. Pat. No. 6,252,665 (issued Jun. 26, 2001), “Lithography using quantum entangled particles”, and in further publications along these lines, in which only the fabrication of two-dimensional patterns is considered. All of this prior art is two-dimensional and does not relate to the invention set forth here, in which the instantaneous fabrication of arbitrary objects in three dimensions, to desired specifications, may be achieved.

In our technique of three-dimensional entangled-photon lithography multiply entangled photons are used. Clusters of mutually-entangled photons, at least some of which take spatially distinct paths, can be designed to almost always arrive simultaneously in the interaction region thereby permitting the use of low optical powers. The region of interaction is defined by where the photon paths are crossed or where the individual constituents of the photon cluster are designed to coexist. The simultaneous absorption of the multiple photons in this volume can result in physical and/or chemical changes of the material, including the deposition or addition of chemical species, the removal of chemical species, the destruction of chemical species, the combination of two or more chemical species, and/or the conversion of one or more chemical species to others.

There are a number of advantages of the proposed technique in comparison with existing techniques. As a result of the highly correlated nature of the photon clusters, high-resolution three-dimensional fabrication can be achieved. The ability to control the interaction region by the use of multiple, spatially distinct photons provides more flexibility in selecting the desired regions of the sample to be modified than if only a single beam is used. Thus resolution higher than that of existing techniques is achievable by our technique. The entangled-photon lithography technique can be adapted in such a way that instead of using only one beam to perform the material modification as in conventional lithography, scanning can be simultaneously performed by the relative times of arrivals of the photons.

The source of light can be continuous or pulsed, and ultrashort pulses can be used to enhance the resolution in the depth direction by using the known techniques of femtosecond imaging. The photons may be directed by optical components to cross at the specimen in a variety of configurations, including at multiple locations. Various optical elements, including optical fibers, mirrors, lenses, diffractive optics, holographic optics, and graded-index optics, can be used to bring the beams to the specimen in different geometrical configurations to enhance the resolution. The scheme can be implemented in a variety of ways, including type-I or type-II parametric downconversion, including spontaneous or stimulated parametric downconversion (a cavity may be present), and downconversion from poled materials. Other sources of entangled photons can be used, such as cascaded atomic emissions. The wavelength used can be in any region of the electromagnetic spectrum, from the radiowave to the x-ray region. Use of the technique is not restricted to photons, but may be implemented using other entities that can be entangled or correlated such as electrons, atoms, and molecules.

In yet another implementation of the invention, a pump beam consisting of multiple wavelengths (derived, for example, from the superposition of multiple laser outputs combined at a beamsplitter) can be used to simultaneously induce reactions in a number of species with multiphoton transitions. Each of these different species can be independently addressed with light of the appropriate wavelength. Moreover, the species may be responsive to different numbers of photons. For example, one species may respond to two-photon excitation while another responds to three-photon excitation.

Another embodiment of the present invention directs the individual entangled photons to a fourth-order interferometer, such as a beamsplitter or a Mach-Zehnder interferometer. The interferometer output then impinges on the specimen. One purpose of the interferometer is to reduce the entanglement volume and thereby to improve the lithographic resolution capabilities of the system. As one example, degenerate signal and idler photons in a two-photon implementation could be directed to a Hong-Ou-Mandel beamsplitter-interferometer with the path lengths adjusted to provide minimum coincidence for photons emitted from the two output ports. The light at either of the beamsplitter output ports will then contain a preponderance of entangled-photon pairs, so that a specimen placed at an output port automatically encounters pairs of entangled photons. The proportion of entangled-photon pairs at the output port is adjustable by modifying the path-length difference of the signal and idler beams before they impinge on the beamsplitter. This configuration obviates the necessity of using crossed signal and idler photon beams and having to very carefully position the specimen. Furthermore, higher-order multiport beamsplitters (for example, a tritter) can be used to produce more than two beams, which would then be subsequently recombined at the specimen.

### SUMMARY OF THE INVENTION

The present invention relates to novel three-dimensional fabrication using entangled-photon lithography. The systems include a source of light that produces twin or multiply entangled photons. The systems also include optical components that direct the twin or multiply entangled photons towards an interaction region. The interaction region includes absorption means responsive to a particular range of energies, which approximately equals the sum of the energies of the entangled photons.

### BRIEF DESCRIPTION OF THE DRAWINGS

FIG. 1 is a diagram illustrating photon arrivals from a classical light source.

FIG. 2 is a plot of the rate of classical-light two-photon absorption versus the classical-light photon-flux density.

FIG. 3 is a plot of the rate of classical-light two-photon absorption and entangled-light two-photon absorption versus the photon-flux density.

FIG. 4 is a diagram illustrating photon arrivals in distinct spatial directions from an ideal entangled light source.

FIG. 5 is a diagram illustrating photon arrivals from an ideal entangled light source using an imaging system.

FIG. 6 is a diagram of one implementation of a three-dimensional entangled-photon lithography system in accordance with the present invention.

FIG. 7 is a diagram illustrating generation of entangled-photon pairs and entangled-photon absorption.

FIG. 8 is a diagram illustrating photon arrivals from a real (non-ideal) entangled light source.

### DETAILED DESCRIPTION OF THE PREFERRED EMBODIMENTS

As embodied and broadly described herein, the present invention is directed to novel apparatuses and methods for three-dimensional entangled-photon lithography that generate a plurality of entangled photons which, when brought together in an interaction region, result in the absorption by target material of multiply entangled photons. Such absorption can result in physical and/or chemical changes of the target material, including the deposition or addition of chemical species, the removal of chemical species, the combination of two or more chemical species, and/or the conversion of chemical species to other chemical species. Given the unique nature of the source of entangled photons, absorption of multiply entangled photons may occur at low optical power, thereby providing a system which allows the preparation of a wide range of structures with minimal damage to ancillary portions of the structure through which the light passes or on which it is incident. Such damage can be particularly deleterious when sensitive materials are exposed to high light intensities, which is required in the conventional two-photon fabrication process. Low light levels also minimize disturbances of the natural absorption energies of the sample, such as those that arise from Stark shifts.

The present invention takes advantage of the distinctions between multiphoton absorption from a classical light source and multiphoton absorption from an entangled-photon light source. This is most readily explained in terms of two-photon absorption of entangled-photon pairs although it is understood that the invention more generally applies to multiphoton absorption of multiply entangled photons. The absorption process may be regarded as having two steps: (1) the first photon initiates a transition to an intermediate (real or virtual) state; and (2) the second photon brings about a transition to the final state of the target material.

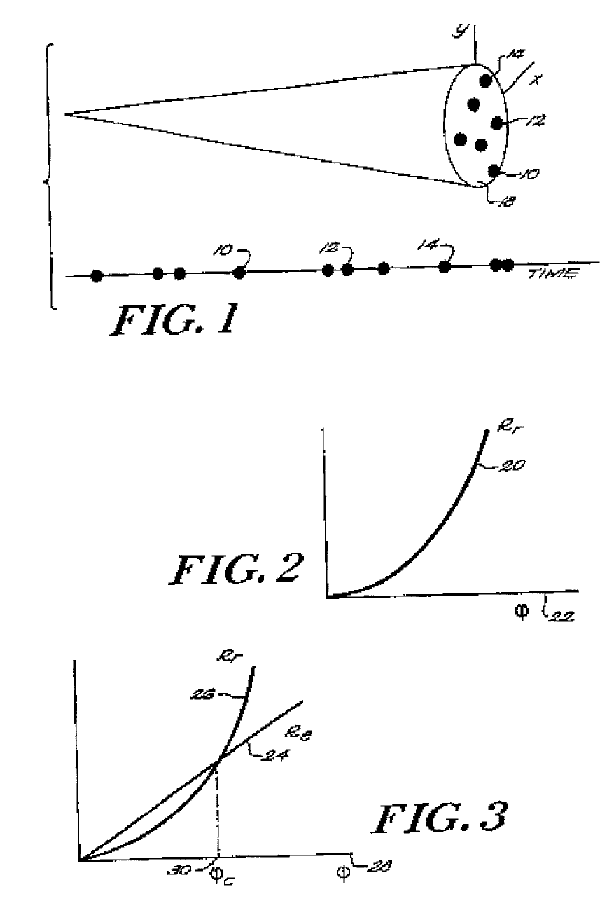

For randomly arriving photons from a classical source of light, probabilistic analysis yields a transition rate Rᵣ (absorptions per second) that depends only on the target material's single-photon cross section σ and virtual-state lifetime τ. As shown in FIG. 1, classical photons arrive randomly and independently. The photons arrive in time in Poisson fashion, as illustrated on the time line by photons 10, 12, and 14. The photons arrive in space in uniformly distributed fashion, as illustrated by photons 10, 12, and 14 at the plane 18. The probability of arrival of one photon in time τ and area σ, when the incident photon-flux density is φ (photons/sec-m²), equals φστ. The probability of accidental arrival of two photons in time τ and area σ equals (φστ)². The resulting rate of classical two-photon absorption is therefore Rᵣ=δᵣφ², where δᵣ=σ²τ. As shown in FIG. 2, the rate of two-photon absorption Rᵣ 20 for a classical light source is dependent on the square of the photon-flux density φ 22.

Now consider correlated photon pairs from an entangled-photon source arriving at the absorbing medium with photon-flux density φ/2 photon-pairs/sec-m². In this case, the absorption rate of the material depends on the probability ξ(Tₑ) that the two photons emitted within the time Tₑ arrive within τ and the probability ζ(Aₑ) that the two photons emitted within the area Aₑ arrive within σ. Thus, the rate of entangled two-photon absorption is Rₑ=σₑφ, with cross section σₑ=½σξ(Tₑ) ζ(Aₑ). If τ<<Tₑ, ξ(Tₑ) equals τ/Tₑ; and if σ<<Aₑ, ζ(Aₑ) equals σ/Aₑ, whereupon the rate of absorption Rₑ=σ(τTₑ) (σ/Aₑ) (φ/2) so that σₑ=½σ(τ/Tₑ) (σ/Aₑ)=δᵣ/2AₑTₑ. The entangled two-photon absorption rate Rₑ must be supplemented by that representing the accidental arrival of pairs within τ and σ, resulting in an overall two-photon absorption rate R=Rₑ+Rᵣ=σₑφ+δᵣφ². As shown in FIG. 3, the correlated two-photon absorption rate Rₑ 24 dominates the random two-photon absorption rate Rᵣ 26 for sufficiently small values of the photon-flux density φ 28. The critical photon-flux density 30 at which the two processes are equal is φ_{c}=σₑ/δᵣ.

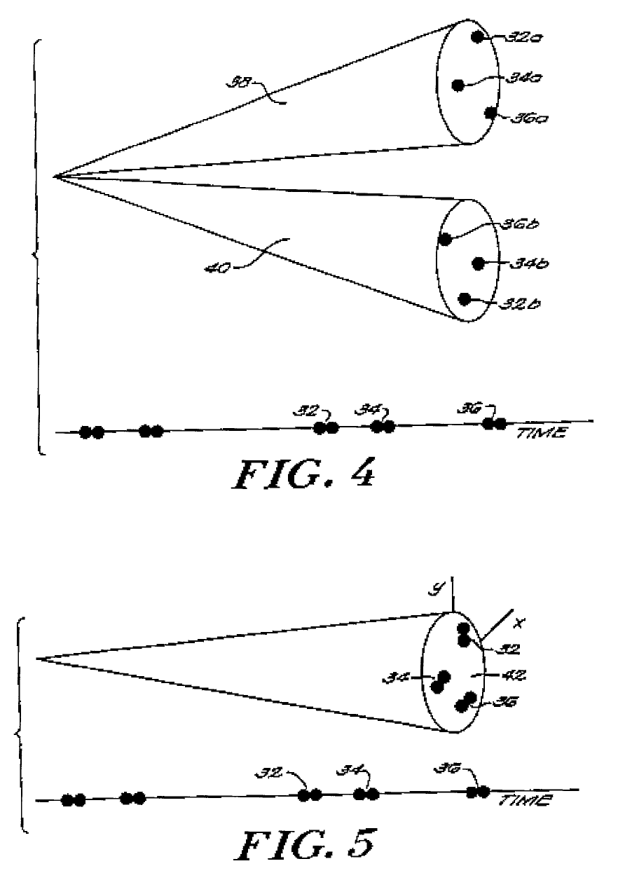

The phenomenon of correlated two-photon absorption may be illustrated by considering an ideal entangled light source. As shown in FIG. 4, photons of an ideal entangled light source arrive in perfect pairs. The two photons of a pair arrive simultaneously, as illustrated on the time line by photon pairs 32, 34, and 36. The two photons of a pair also arrive at matched positions, as illustrated by photons 32a and 32b, 34a and 34b, and 36a and 36b. Each photon-arrival position in the first beam 38 has one and only one corresponding matched photon-arrival position in the second beam 40.

Using an imaging system, the matching photon pairs can be brought together at a target location 42 so that they arrive simultaneously at the same position, as shown in FIG. 5. Photon pairs 32, 34, and 36 are matched in time, as illustrated on the time line, and matched in spatial location, as illustrated at the target location 42.

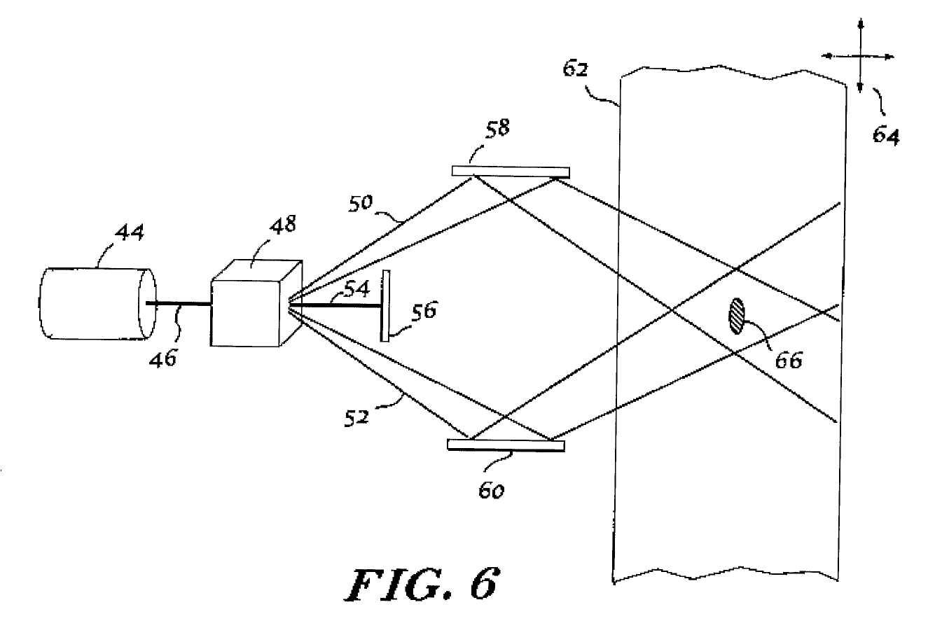

The present invention applies these characteristics of ideal entangled light. One embodiment of the present invention is shown in FIG. 6. A source of light 44 provides a pump beam 46, which is passed through a nonlinear optical medium 48. The source of the pump beam may be a laser, semiconductor laser, light-emitting diode, incandescent source, or other similar light source. The light source 44 provides light in the form of a beam of photons. The light may be continuous-wave or pulses of, for example, attosecond or longer duration. The light preferably has energy in the wavelength range from radiowaves to x-rays.

The nonlinear optical medium 48 may be a crystal, a surface, an interface or other similar component. The nonlinear optical medium 48 causes a portion of the pump beam 46 to split into a signal beam 50 and an idler beam 52 (referred to collectively as twin beams), contributing a stream of daughter signal entangled photons 50 and a corresponding stream of daughter idler entangled photons 52. The signal 50 and idler 52 photons may be referred to as entangled photons (also called twin-photons or two-mode squeezed-state photons). The interaction of the pump beam 46 with the nonlinear optical medium 48 generates entangled photons by means of a nonlinear optical process, such as spontaneous parametric downconversion.

Ideal spontaneous parametric downconversion (SPD) splits each pump-beam photon into twin daughter photons that are emitted simultaneously. Since energy and momentum are conserved in the splitting process, the daughter photons share the energy and momentum of the mother. This entangles the directions of the two daughters so that the emission of one photon in a given direction is associated with a certain simultaneous emission of a twin photon in a matching direction. The twins may have the same frequency (wavelength or color), in which case they are identical (or degenerate); or differ in frequency (wavelength or color), in which case they are in a sense fraternal (or nondegenerate). The entanglement persists no matter how far away the photons might be from each other.

Referring to FIG. 6, the residual pump photons 54 that fail to be split are incident on a filter (or beam dump ) 56 that absorbs them. Alternatively they could be re-used by redirecting them back to the nonlinear optical medium 48. The signal 50 and idler 52 photons are then directed towards the three-dimensional structure being fabricated 62 by optical components 58 and 60. The optical components may include mirrors, lenses, prisms, gratings, static or dynamic holographic components, graded-index optical components, optical fibers, optical-fiber components or other similar light-directing mechanisms. The optical components 58 and 60 may be arranged such that entangled-photon pairs arrive within the three-dimensional entanglement volume 66, which can be made arbitrarily small and which lies within a selected portion of the structure under fabrication 62. Entangled-photon-pair absorption occurs when an entangled signal photon 50 and its companion idler photon 52 come together within the entanglement volume 66. Entangled-photon pairs are engineered such that they arrive simultaneously and are simultaneously absorbed in a specified three-dimensional interaction region, where they can result in physical and/or chemical changes of the material, including the deposition or addition of chemical species, the removal of chemical species, the combination of two or more chemical species, and/or the conversion of chemical species to others. A three-dimensional structure is fabricated using entangled-photon lithography by relative motion 64 of the three-dimensional structure being fabricated with respect to the entanglement volume 66. The region of interaction is defined by where entangled-photon pairs arrive simultaneously.

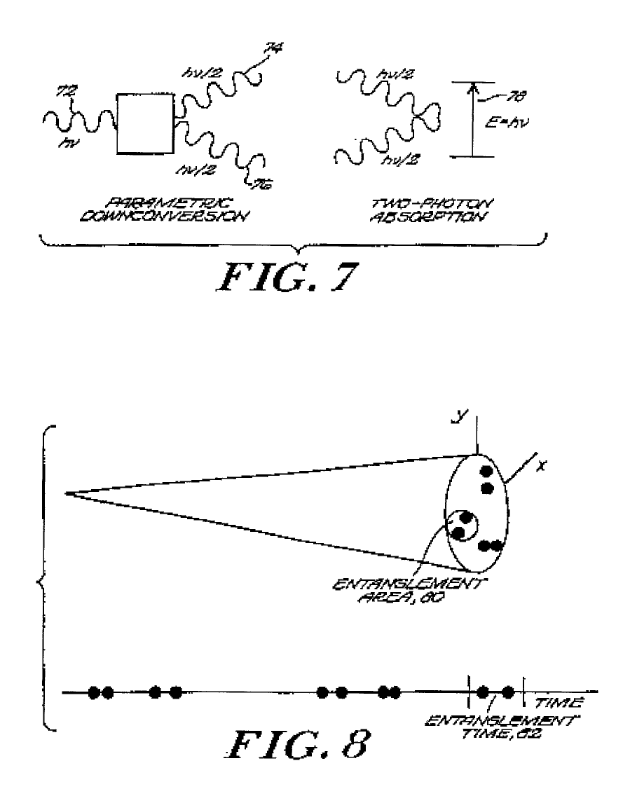

Two principal properties of ideal entangled-photon pairs are the coincidence of the emission times of the photons in two matching directions and the one-to-one correspondence between the path of one photon and the matching path of the other photon. Un-entangled signal and idler photons arrive randomly in time, and thus exhibit statistical fluctuations (i.e., noise) identical to that of a classical light beam. However, when considering pairs of photons that are entangled, the present invention takes advantage of the matching characteristics of the daughter photons. As shown in FIG. 7, conservation of energy and momentum guarantees this matching of the times and directions of emission of the two entangled photons created from one incoming pump photon. The incoming pump photon 72 has an incoming energy equal to hv. The incoming pump photon is split into two daughter photons 74 and 76 having energies whose sum is hv. In the general nondegenerate case, they split unequally whereas in the special degenerate case depicted in FIG. 7 they split equally so that each daughter photon has energy equal to hv/2. Upon absorption of the daughter photons simultaneously arriving at the same positions of a two-photon absorbing medium, the sum of the energies of the two absorbed daughter photons is hv, matching the energy required for entangled two-photon absorption to occur. Parametric downconversion and two-photon absorption are seen to be dual processes.

One embodiment of the present invention, which serves as a useful example, makes use of a real (non-ideal) light source of quantum-mechanically entangled photons, which exhibit photon-pair occurrence times that are highly correlated. The entangled-photons are generated by type-I SPD. Because energy is conserved in the entangled-pair creation process, the twin photons are produced nearly simultaneously and each has a wavelength longer than the original. Momentum is also conserved, resulting in a nearly one-to-one correspondence between the directions of travel of each photon in an entangled pair. Because they share the energy and momentum of the original photon, the twin photons are said to be “entangled” with each other.

The two photons of each pair arrive at random positions within a small area Aₑ, called the entanglement area 80, as shown in FIG. 8. The two photons also arrive at random within a small time interval Tₑ, called the entanglement time 82. The spatial resolution of the system is dependent on, among other things, the entanglement angle. The entanglement angle is the angular width of the cone of directions entangled with one direction of a twin photon. A number of factors influence the size of the entanglement angle, including the spectral width and beam width of the laser, as well as the interaction volume of the nonlinear optical medium. Entanglement angles are typically of the order of tenths of milliradians, so that thousands of independent entangled patches can be used for twin-photon excitation. The temporal resolution of the system is dependent on, among other things, the entanglement time, which typically ranges from femtoseconds to picoseconds. Both the entanglement angle and the entanglement time can be adjusted to optimize system performance.

Another advantage of this type of scheme is that longer-wavelength excitation radiation can generally reach the interior of a sample more easily because target material is often penetrated more deeply by photons of longer wavelength.

In other embodiments of the present invention, the entangled-photons are generated by processes other than type-I SPD, and photons are emitted in separate (non-collinear) or in the same (collinear) directions. For example, the photons may be generated by type-II SPD, in which the photons are emitted in the same (or in separate directions) but with different polarizations. Alternatively, the photons may be generated by SPD in poled or unpoled optical fibers or materials, or at a surface or an interface, or directly at the source or surface of the device producing the pump beam. The photons may be generated by spontaneous parametric downconversion or by stimulated parametric downconversion or by cascaded atomic emissions. With cascaded atomic emissions, a pump beam is incident on a material that emits a cascade of two photons, entangled via energy and momentum conservation.

The two photons can be directed by optical components 58 and 60 in FIG. 6 to cross each other in such a way that entangled-photon pairs arrive simultaneously within an arbitrarily selected volume, at an arbitrarily selected position of the structure being fabricated. This is called path-delay tuning. One or both of the optical components 58 and 60 are moved or altered so that the position and size of the entanglement region changes. The optical components 58 and 60 may be arranged such that the photons cross at the specimen in a variety of configurations, including at multiple locations. The optical components may be moved mechanically, electronically, acoustically and/or optically. The moveability of the optical components allows shifting of the focal plane in the transverse (x-y) direction and/or the axial (z) direction. This enables access to different locations within the three-dimensional structure being fabricated. Regions in which simultaneous photon arrivals occur can therefore be systematically changed by modifying the optical-component position. Accordingly, lateral and axial scanning of the excitation region is achieved optically.

Excitation of the target material occurs only when the energy of two daughter entangled photons are combined within a specified entanglement time. Prior to absorption of any daughter entangled photons, the target material is in a lower energy state. When a first twin photon reaches the target material in the structure being fabricated, it rises to an intermediate (real or virtual) energy state. If the companion entangled photon arrives within a specified entanglement time and entanglement area, then the target material in the interaction region is excited to its upper energy state. This upper energy may be narrow band. Therefore, if the arrival of the second twin photon is time-delayed beyond the entanglement time, not all (or perhaps none) of the daughter photons will be absorbed in time to cause absorption. Accordingly, one can arrange the optical components(s) in such a way that only absorbants in a limited adjustable region reach the upper energy level and thereby result in physical and/or chemical changes of the material, including the deposition or addition of chemical species, the removal of chemical species, the combination of two or more chemical species, and/or the conversion of chemical species to others.

Either or both of the optical components 58 and 60 may also be arranged such that the arrival of twin photons at a given location (or locations) within the interaction region occurs with a specified time delay. This is called relative path-delay tuning. There may be situations where it is desirable for twin photons to arrive in the interaction region with a specified short or long relative time delay, which can enhance the two-photon absorption rate and therefore chemical changes attendant to the fabrication process. By moving or altering at least one of the optical components, the arrival of the twin photon corresponding to the moved optical component(s) can be delayed. The entangled-photon pairs, with relative time delay between their photons may be brought, by focusing or imaging, to a small, but adjustable, region. This allows the precise targeting of a location or locations within the structure under fabrication.

Pump-beam 46 characteristics such as the spectral width and beam width, and nonlinear material 48 characteristics such as the crystal length and orientation, can be adjusted to generate entangled photons with adjustable entanglement time. This is called entanglement-time tuning. Certain values of the entanglement time result in an enhancement of the two-photon absorption rate, thereby permitting lower pump-beam intensities to be used in the fabrication process. This, in turn, can reduce damage to ancillary portions of the structure.

Path-delay tuning, relative path-delay tuning, and entanglement-time tuning can be combined to create adjustable interaction regions where the two-photon absorption rate is optimized. This, in turn, permits optically achieved lateral and axial scanning with enhanced fabrication resolution (width of region of effective photon-pair arrivals) and localization (decay of region of effective photon-pair arrivals with distance). In conventional two-photon lithography, these quantities are determined by the quadratic intensity dependence of the absorption rather than by the intersection of beams.

In another embodiment of the invention, one or more pulsed or continuous-wave auxiliary (or control) light beams are directed toward the interaction region to further enhance entangled-photon absorption. The sources of the control light beams may be a laser, fluorescence light produced by the interaction or by the chemical process initiated, or by an externally supplied light source. This control light serves to couple the initial, intermediate, and/or final states of the target material to other states, thereby enhancing the entangled-photon absorption rate. Alternatively, this control light serves as a pump to provide high occupancy of the intermediate state, thereby maintaining the material in a state of readiness to respond to incoming photons.

In other embodiments of the present invention, nonlinear optical processes are used to generate multiply entangled photons (three, four, and more) that may travel in two or more distinct spatial directions. Triples and quadruples of entangled photons are obtained from a higher-order downconverter, from a cascade of two-photon downconverters, or from atomic cascades (for example, an atom cascading through two intermediate levels to produce three entangled photons). Thus, multiphoton (e.g., three-photon) implementations of the invention are possible. These photons are brought together at a structure to produce multiphoton absorption (i.e., absorption of three, four, or more photons) in a selected entanglement volume.

In yet another implementation of the invention, a pump beam consisting of multiple wavelengths (derived, for example, from the superposition of multiple laser outputs combined at a beamsplitter) is used to simultaneously excite a number of types of absorbers with multiphoton transitions, resulting in a panoply of physical and/or chemical changes of the material. Each of these different changes can be effected independently so that structures with complex features can be fabricated at one time. Different elements of the structure can be responsive to entangled multiphoton absorption of different orders. For example, one physical or chemical change may respond to two-photon excitation while another responds to three-photon excitation.

Another embodiment of the present invention directs the signal and idler photons to a fourth-order interferometer, such as a beamsplitter or a Mach-Zehnder interferometer. The interferometer output then impinges on the target material in the structure under fabrication. One purpose of the interferometer is to reduce the entanglement volume and thereby to improve the image-resolution capabilities of the system. As one example, degenerate signal and idle beams are directed to a Hong-Ou-Mandel beamsplitter-interferometer with the path lengths adjusted to provide minimum coincidence for photons emitted from the two output ports. The light at either of the beamsplitter output ports then contains a preponderance of entangled-photon pairs, so that a structure placed at an output port automatically encounters entangled-photon pairs. The proportion of entangled-photon pairs at the output port is adjustable by modifying the path-length difference of the signal and idler photons before they impinge on the beamsplitter. This configuration obviates the necessity of using crossed signal and idler photons and having to position the specimen very carefully. Furthermore, higher-order multi-port beamsplitters (for example, a tritter) can be used to produce more than two beams, which would then be subsequently recombined at the target material.

Although it might be desirable to use a pulsed source of entangled photons, the low light levels required for the present invention enable continuous wave sources of light to be used. For photon pairs that are relatively monochromatic, this can result in a substantial reduction of the deleterious effects associated with dispersive broadening of short optical pulses, and improved beam control. Even for non-monochromatic and pulsed entangled-photon pairs, however, dispersive broadening can be non-locally canceled by proper choice of optical materials as a result of anticorrelations in the frequency components of the twin photons, engendered by energy conservation. In the case where the twin photons travel through materials having dispersion coefficients approximately equal in magnitude and opposite in sign, for example, the photon arrivals will remain coincident. The present invention can therefore accommodate the use of optical fibers for the transport and processing of light. In the conventional implementation of two-photon lithography, in contrast, femtosecond-duration optical pulses are substantially broadened and reduced in magnitude by the dispersion associated with transmission through the optical components of the fabrication microscope, thereby decreasing the two-photon absorption probability. The optical pulse duration must therefore be chosen to be sufficiently long to avoid this effect in fiber-based conventional two-photon lithography systems. The fact that optical fibers can be used to transport light in the present invention opens the possibility of carrying out three-dimensional near-field entangled-photon lithography.

Chemical and physical changes in materials with narrow two-photon absorption spectra can be effected with the present invention because the frequency spectrum of the summed energy of the entangled-photon pair is narrow. This, again, results from anticorrelations in the frequency components of the photon pair. In conventional two-photon lithography, the peak of the target material's absorption spectrum must be sufficiently broad to accommodate the spread in the summed energy of the two independent photons, necessitating the use of optical pulses that are not too short.

The present invention also accounts for the fact that the absorptive properties of a target material in the structure under fabrication depend in a complex manner on the state of the excitation light, including whether the photons are or are not entangled.

Although only the use of entangled photons has been described in fabricating three-dimensional structures, the present invention may also use pairs of other entities, such as electrons, atoms, molecules, or photons that are correlated in time and/or space but not necessarily entangled.

As a result of the entangled nature of the photon pairs, the absorption rate is substantially enhanced and lower optical power can be used for effecting changes in the target material in the interaction region and thereby for fabricating three-dimensional structures. This approach is particularly useful when low light levels are mandatory for avoiding damage to sensitive target materials in which it is desired to achieve chemical and/or physical changes. Examples include single atoms, single molecules, caged compounds, biological molecules, biological tissues, and living neurons. The ability to control the position of the interaction region by use of entangled photons that travel in spatially distinct directions provides more flexibility in selecting the desired region than if only a single beam is used, and provides a mechanism for optically implemented three-dimensional scanning. The technique provides higher resolution and enhanced depth focus for fabrication than is possible with existing techniques.

Moreover, a wide variety of absorber materials and effects resulting from the absorption of entangled photons may be used in conjunction with, or as precursors to, the chemical and/or physical changes associated with the fabrication of three-dimensional structures via entangled-photon lithography. Upon entangled-photon absorption, the three-dimensional target material (or deliberately deposited ancillary material) may change form or undergo a phase transition; or as an intermediate step may alter local ambient conditions such as voltage, current flow, electric field, magnetic field, and pH, among other conditions; or as an intermediate step entangled-photon absorption may produce entangled-photon luminescence, entangled-photon photoemission, entangled-photon photo-activation, entangled-photon un-caging, entangled-photon photo-acoustic absorption, entangled-photon ionization, and/or entangled-photon localized release of chemicals, in the course of the fabrication process. These or other schemes based upon entangled-photon absorption can then be used, for instance, to induce specific chemical reactions that lead to polymerization, oxidation, reduction, deposition (as of metals, semiconductors, or insulators), decomposition of chosen chemical species, and/or preparation for a further photochemical or non-photochemical reaction.

Other embodiments and uses of the invention will be apparent to those skilled in the art from consideration of the specification and practice of the invention disclosed herein. The specification and examples should be considered exemplary only.

We claim:

1. An entangled-photon three-dimensional lithography system, comprising:
a source of light, said source of light providing a pump beam of photons;
a nonlinear optical medium, said nonlinear optical medium receiving said pump beam and splitting a portion of said pump beam into a first twin beam and a second twin beam, wherein daughter entangled photons are contributed to said first twin beam and corresponding daughter entangled photons are contributed to said second twin beam; and
a plurality of moveable beam-directing components for directing each of said twin beams towards a three-dimensional target material, wherein said target material includes chemical means responsive to target excitation.

2. An entangled-photon three-dimensional lithography system according to claim 1, wherein said first and second twin beams are generated by parametric downconversion.

3. An entangled-photon three-dimensional lithography system according to claim 1, wherein said first and second twin beams are generated by parametric downconversion in an amplifying configuration.

4. An entangled-photon three-dimensional lithography system according to claim 1, wherein entangled-photon pairs arrive nearly simultaneously at a selected and adjustable small region in said target material, wherein each of said entangled-photon pairs comprises one of said daughter entangled photons and one of said corresponding daughter entangled photons.

5. An entangled-photon three-dimensional lithography system according to claim 4, wherein said target material includes deliberately deposited ancillary material to facilitate three-dimensional fabrication.

6. An entangled-photon three-dimensional lithography system according to claim 4, wherein said target material may change form.

7. An entangled-photon three-dimensional lithography system according to claim 4, wherein said target material may undergo a phase transition.

8. An entangled-photon three-dimensional lithography system according to claim 4, wherein said target material may, as an intermediate step, alter the local ambient voltage.

9. An entangled-photon three-dimensional lithography system according to claim 4, wherein said target material may, as an intermediate step, alter the local ambient current flow.

10. An entangled-photon three-dimensional lithography system according to claim 4, wherein said target material may, as an intermediate step, alter the local ambient electric field.

11. An entangled-photon three-dimensional lithography system according to claim 4, wherein said target material may, as an intermediate step, alter the local ambient magnetic field.

12. An entangled-photon three-dimensional lithography system according to claim 4, wherein said target material may, as an intermediate step, alter the local ambient pH.

13. An entangled-photon three-dimensional lithography system according to claim 4, wherein said target material may, as an intermediate step, alter the local ambient pH.

14. An entangled-photon three-dimensional lithography system according to claim 4, wherein said target material may, as an intermediate step, alter the local ambient temperature.

15. An entangled-photon three-dimensional lithography system according to claim 4, wherein said target material may, as an intermediate step, alter the local ambient volume.

16. An entangled-photon three-dimensional lithography system according to claim 4, wherein said target material may, as an intermediate step, alter the local ambient pressure.

17. An entangled-photon three-dimensional lithography system according to claim 4, wherein said target material may, as an intermediate step, produce entangled-photon luminescence in the course of the fabrication process.

18. An entangled-photon three-dimensional lithography system according to claim 4, wherein said target material may, as an intermediate step, produce entangled-photon photoemission in the course of the fabrication process.

19. An entangled-photon three-dimensional lithography system according to claim 4, wherein said target material may, as an intermediate step, produce entangled-photon photo-activation in the course of the fabrication process.

20. An entangled-photon three-dimensional lithography system according to claim 4, wherein said target material may, as an intermediate step, produce entangled-photon uncaging in the course of the fabrication process.

21. An entangled-photon three-dimensional lithography system according to claim 4, wherein said target material may, as an intermediate step, produce entangled-photon photoacoustic absorption in the course of the fabrication process.

22. An entangled-photon three-dimensional lithography system according to claim 4, wherein said target material may, as an intermediate step, produce entangled-photon ionization in the course of the fabrication process.

23. An entangled-photon three-dimensional lithography system according to claim 4, wherein said target material may, as an intermediate step, produce entangled-photon localized release of chemicals in the course of the fabrication process.

24. An entangled-photon lithography system according to claim 4, wherein said target material undergoes a specific chemical reaction that leads to polymerization.

25. An entangled-photon three-dimensional lithography system according to claim 4, wherein said target material undergoes a specific chemical reaction that leads to oxidation.

26. An entangled-photon three-dimensional lithography system according to claim 4, wherein said target material undergoes a specific chemical reaction that leads to reduction.

27. An entangled-photon three-dimensional lithography system according to claim 4, wherein said target material undergoes a specific chemical reaction that leads to deposition of a chosen material.

28. An entangled-photon three-dimensional lithography system according to claim 4, wherein said target material undergoes a specific chemical reaction that leads to the decomposition of chosen chemical species.

29. An entangled-photon three-dimensional lithography system according to claim 4, wherein said target material undergoes a specific preparation for a further photochemical reaction.

30. An entangled-photon three-dimensional lithography system according to claim 4, wherein said target material undergoes a specific preparation for a further non-photochemical reaction.

31. An entangled-photon three-dimensional lithography system according to claim 4, wherein said target material releases biological substances via photo-activation.

32. An entangled-photon three-dimensional lithography system according to claim 4, wherein said target material releases chemicals via photo-activation.

33. An entangled-photon three-dimensional lithography system according to claim 1, wherein at least one of said moveable beam-directing components is moved mechanically.

34. An entangled-photon three-dimensional lithography system according to claim 1, wherein at least one of said moveable beam-directing components is moved electrically.

35. An entangled-photon three-dimensional lithography system according to claim 1, wherein at least one of said moveable beam-directing components is moved acoustically.

36. An entangled-photon three-dimensional lithography system according to claim 1, wherein at least one of said moveable beam-directing components is moved optically.

37. An entangled-photon three-dimensional lithography system according to claim 4, wherein the arrival of said entangled-photon pairs is adjusted by path-delay tuning.

38. An entangled-photon three-dimensional lithography system according to claim 4, wherein the arrival of said entangled-photon pairs is adjusted by relative-path-delay tuning.

39. An entangled-photon three-dimensional lithography system according to claim 4, wherein the arrival of said entangled-photon pairs is adjusted by entanglement-time tuning.

40. An entangled-photon three-dimensional lithography system according to claim 4, wherein the arrival of said entangled-photon pairs is simultaneously adjusted by relative-path-delay tuning and entanglement-time tuning.

41. An entangled-photon three-dimensional lithography system according to claim 40, further comprising Fourier-transform analysis means for providing spectroscopic information about the fabrication.

42. An entangled-photon three-dimensional lithography system according to claim 1, wherein said beam-directing components include at least one dispersive optical component.

43. An entangled-photon three-dimensional lithography system according to claim 1, wherein said beam-directing components include at least one graded-index optical component.

44. An entangled-photon three-dimensional lithography system according to claim 1, wherein said beam-directing components include optical-fiber components.

45. An entangled-photon three-dimensional lithography system according to claim 1, further comprising at least one auxiliary beam directed towards said target material.

46. An entangled-photon three-dimensional lithography system according to claim 1, wherein said pump beam comprises multiple wavelengths.

47. An entangled-photon three-dimensional lithography system, comprising:
a source of light, said source of light providing a pump beam of photons;
a nonlinear optical medium, said nonlinear optical medium receiving said pump beam and splitting a portion of said pump beam into a plurality of entangled beams; and
a plurality of moveable beam-directing components for directing each of said entangled beams towards selected and adjustable points in a target material, wherein said target material includes chemical means responsive to target excitation.

48. An entangled-photon three-dimensional lithography system, comprising:
a source of light, said source of light providing a pump beam of photons;
a nonlinear optical medium, said nonlinear optical medium receiving said pump beam and splitting a portion of said pump beam into a first twin beam and a second twin beam, wherein daughter entangled photons are contributed to said first twin beam and corresponding daughter entangled photons are contributed to said second twin beam; and
an interferometer, wherein said interferometer receives each of said twin beams and directs said twin beams towards a target material, said target material including chemical means responsive to target excitation.

49. A correlated-pair three-dimensional lithography system, comprising:
a first beam and a second beam, wherein correlated entities are contributed to said first beam and corresponding correlated entities are contributed to said second beam; and
a plurality of moveable beam-directing components for directing each of said beams towards a target material, wherein said target material includes chemical means responsive to target excitation.

50. A correlated-photon three-dimensional lithography system, comprising:
a source of light, said source of light providing a pump beam of photons;
a nonlinear optical medium, said nonlinear optical medium receiving said pump beam and splitting a portion of said pump beam into a first beam and a second beam, wherein correlated photons are contributed to said first beam and corresponding correlated photons are contributed to said second beam; and
a plurality of moveable beam-directing components for directing said first beam and said second beam towards a target material.

51. A correlated-photon three-dimensional lithography system according to claim 50, wherein said pump beam comprises bunched photons.

52. A correlated-photon three-dimensional lithography system according to claim 50, wherein said pump beam comprises super-Poissonian photons.

53. A correlated-photon three-dimensional lithography system according to claim 50, wherein said pump beam comprises multiple wavelengths.

54. A correlated-photon three-dimensional lithography system according to claim 50, wherein at least one of said moveable beam-directing components is moved mechanically.

55. A correlated-photon three-dimensional lithography system according to claim 50, wherein at least one of said moveable beam-directing components is moved electrically.

56. A correlated-photon three-dimensional lithography system according to claim 50, wherein at least one of said moveable beam-directing components is moved acoustically.

57. A correlated-photon three-dimensional lithography system according to claim 50, wherein at least one of said moveable beam-directing components is moved optically.

58. A correlated-photon three-dimensional lithography system according to claim 50, wherein the arrival of said first beam and said second beam is adjusted by path-delay tuning.

59. A correlated-photon three-dimensional lithography system according to claim 50, wherein the arrival of said first beam and said second beam is adjusted by relative-path-delay tuning.

60. A correlated-photon three-dimensional lithography system according to claim 50, further comprising at least one source of auxiliary light directed towards said target material.

61. A correlated-photon three-dimensional lithography system, comprising:
a source of light, said source of light providing a pump beam of photons;
a nonlinear optical medium, said nonlinear optical medium receiving said pump beam and splitting a portion of said pump beam into a first beam and a second beam, wherein correlated photons are contributed to said firm beam and said second beam;
an interferometer, wherein said interferometer receives said first beam and said second beam and directs said first beam and second beam towards a target material, said target material including chemical means responsive to target excitation; and a plurality of moveable beam-directing components for directing said first beam and said second beam towards selected and adjustable points in a target material, wherein said target material includes chemical means responsive to target excitation.

62. A method of correlated-photon three-dimensional lithography, comprising the steps of:
providing a pump beam of photons;
receiving said pump beam and splitting a portion of said pump beam into a first beam and a second beam, wherein correlated photons are contributed to said first beam and corresponding correlated photons are contributed to said second beam; and
directing said first beam and said second beam towards selected and adjustable points in a target material, wherein said target material includes chemical means responsive to target excitation.
